(19) United States
(12) Patent Application Publication
(10) Pub. No.: US 2025/0157815 A1
(43) Pub. Date: May 15, 2025

(54) SELECTIVE FEATURE MODIFICATION USING DIRECTIONAL DEPOSITION

(71) Applicant: Applied Materials, Inc., Santa Clara, CA (US)

(72) Inventors: Tassie ANDERSEN, Salem, MA (US); Shurong LIANG, Lynnfield, MA (US)

(73) Assignee: Applied Materials, Inc., Santa Clara, CA (US)

(21) Appl. No.: 18/510,630

(22) Filed: Nov. 15, 2023

(51) Int. Cl. H01L 21/02; C23C 14/22; H01J 37/32; H01L 21/3065

(52) U.S. Cl. CPC H01L 21/02636; C23C 14/221; H01J 37/32623; H01L 21/3065; H01J 2237/3341

(57) ABSTRACT

Disclosed herein are approaches for using angle control of deposition plus etch processes to enable 2D and/or 3D device patterning. In one approach, a method may include providing a substrate including a plurality of trenches having different dimensions, and depositing a film atop the substrate. The film may be delivered at a non-zero angle relative to a perpendicular extending from a top surface of the substrate, wherein an amount of the film formed along a bottom surface of a first trench is greater than an amount of the film formed along a bottom surface of a second trench. The method may further include delivering ions into the substrate in a reactive ion etching process to remove material from at least one of: the first sidewall of the first trench, the bottom surface of the second trench, and the film.

### FIELD OF THE DISCLOSURE

The present disclosure relates to semiconductor structures and, more particularly, to selective trench modification using one or more angled material deposition processes and one or more etch processes.

### BACKGROUND OF THE DISCLOSURE

As semiconductor devices continue to scale to smaller dimensions, the ability to pattern features becomes increasingly difficult. These difficulties include, in one aspect, the ability to obtain features at a target size for a given technology generation. Another difficulty is the ability to obtain the correct shape of a patterned feature, as well as the correct placement of a patterned feature. For example, given a fixed ion beam angle, there is a critical aspect ratio above which the ion beam is blocked from reaching the bottom of the trench. At this point lateral etch sharply drops.

With respect to these and other considerations the present improvements may be useful.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a semiconductor layer including a plurality of trenches, wherein a first trench of the plurality of trenches has a first trench width extending in a first direction, wherein a second trench of the plurality of trenches has a second trench width extending in the first direction, wherein the first trench width and the second trench width are different, and wherein the first and second trenches each include a first sidewall opposite a second sidewall, and a bottom surface extending between the first and second sidewalls. The method may further include depositing a film atop the semiconductor layer, wherein the film is delivered at a non-zero angle relative to a perpendicular extending from a top surface of the semiconductor layer, and wherein an amount of the film formed along the bottom surface of the first trench is greater than an amount of the film formed along the bottom surface of the second trench. The method may further include delivering ions into the semiconductor layer in a reactive ion etching process to remove material from at least one of: the first sidewall of the first trench, the bottom surface of the second trench, and the film.

In another aspect, a method may include providing a substrate including a plurality of trenches, wherein a first trench of the plurality of trenches has a first trench width extending in a first direction, wherein a second trench of the plurality of trenches has a second trench width extending in the first direction, wherein the first trench width is greater than the second trench width, and wherein the first and second trenches each include a first sidewall opposite a second sidewall, and a bottom surface extending between the first and second sidewalls. The method may further include depositing a film atop the substrate, wherein the film is delivered at a non-zero angle relative to a perpendicular extending from a top surface of the substrate, and wherein an amount of the film formed along the bottom surface of the first trench is greater than an amount of the film formed along the bottom surface of the second trench. The method may further include delivering ions into the substrate in a reactive ion etching process to remove material from at least one of: the first sidewall of the first trench, the bottom surface of the second trench, and the film.

In yet another aspect, a system may include a substrate including a plurality of trenches, wherein a first trench of the plurality of trenches has a first trench width extending in a first direction, wherein a second trench of the plurality of trenches has a second trench width extending in the first direction, wherein the first trench width and the second trench width are different, and wherein the first and second trenches each include a first sidewall opposite a second sidewall, and a bottom surface extending between the first and second sidewalls. The system may further include a deposition device operable to deposit a film atop the substrate, wherein the film is delivered at a non-zero angle relative to a perpendicular extending from a top surface of the substrate, and wherein an amount of the film formed along the bottom surface of the first trench is greater than an amount of the film formed along the bottom surface of the second trench. The system may further include an etch device operable to deliver ions into the substrate in a reactive ion etching process to remove material from at least one of: the first sidewall of the first trench, the bottom surface of the second trench, and the film.

### BRIEF DESCRIPTION OF THE DRAWINGS

The accompanying drawings illustrate exemplary approaches of the disclosure, including the practical application of the principles thereof, as follows:

FIG. 1A is a top view of a substrate of a semiconductor device, according to embodiments of the present disclosure;

FIG. 1B is a cross-sectional view of a trench along cutline A-A′ of FIG. 1A, according to embodiments of the present disclosure;

FIG. 2A is a top view of the substrate of the semiconductor device, according to embodiments of the present disclosure;

FIG. 2B is a cross-sectional view of the substrate of the semiconductor device of FIG. 2A, according to embodiments of the present disclosure;

FIG. 3A is a top view of the substrate of the semiconductor device, according to embodiments of the present disclosure;

FIG. 3B is a cross-sectional view of the substrate of the semiconductor device of FIG. 3A, according to embodiments of the present disclosure;

FIG. 4A is a top view of the substrate of the semiconductor device, according to embodiments of the present disclosure;

FIG. 4B is a cross-sectional view of the substrate of the semiconductor device of FIG. 4A, according to embodiments of the present disclosure;

FIG. 5A is a top view of the substrate of the semiconductor device, according to embodiments of the present disclosure;

FIG. 5B is a cross-sectional view of the substrate of the semiconductor device of FIG. 5A, according to embodiments of the present disclosure;

FIG. 6A is a top view of the substrate of the semiconductor device, according to embodiments of the present disclosure;

FIG. 6B is a cross-sectional view of the substrate of the semiconductor device of FIG. 6A, according to embodiments of the present disclosure;

FIGS. 7A-7E are top views of a line feature of a semiconductor device during processing to mitigate defects, according to embodiments of the present disclosure;

FIG. 8A is a top view of a substrate of a semiconductor device, according to embodiments of the present disclosure;

FIG. 8B is a cross-sectional view of the semiconductor device of FIG. 8A, according to embodiments of the present disclosure;

FIG. 9A is a top view of the substrate of the semiconductor device, according to embodiments of the present disclosure;

FIG. 9B is a cross-sectional view of the substrate of the semiconductor device of FIG. 9A, according to embodiments of the present disclosure;

FIG. 10A is a top view of the substrate of the semiconductor, according to embodiments of the present disclosure;

FIG. 10B is a cross-sectional view of the substrate of the semiconductor device of FIG. 10A, according to embodiments of the present disclosure;

FIG. 10C is a cross-sectional view of the substrate including ions delivered into a semiconductor layer in a vertical etch process according to embodiments of the present disclosure;

FIG. 11 is a top view of a plurality of trenches in a substrate of a semiconductor device, according to embodiments of the present disclosure;

FIG. 12A-12B are top views of a plurality of trenches in a substrate of a semiconductor device, according to embodiments of the present disclosure;

FIG. 13 illustrates a schematic diagram of a processing apparatus according to embodiments of the present disclosure;

FIG. 14A illustrates an exemplary processing apparatus according to embodiments of the disclosure;

FIG. 14B depicts details of an exemplary extraction plate according to embodiments of the disclosure; and

FIG. 15 shows a semiconductor processing apparatus according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and systems in accordance with the present disclosure will now be described more fully hereinafter with reference to the accompanying drawings, where various embodiments are shown. The methods and systems may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously provide ion beam shadowing to selectively deposit material and to etch certain features in an array of structures, such as trenches and/or lines. More specifically, embodiments herein provide a solution for etching 2-D and 3-D structures so as to avoid specific structures while elongating, deepening or lessening other structures in a complex feature array or arrangement. The aspect ratio of the array structures can be used to selectively etch only some of the areas or structures in the first direction, which may advantageously eliminate one or more masking and etch/EUV steps. As such, features (e.g., trenches) can be elongated in one direction without being elongated in a second, perpendicular direction.

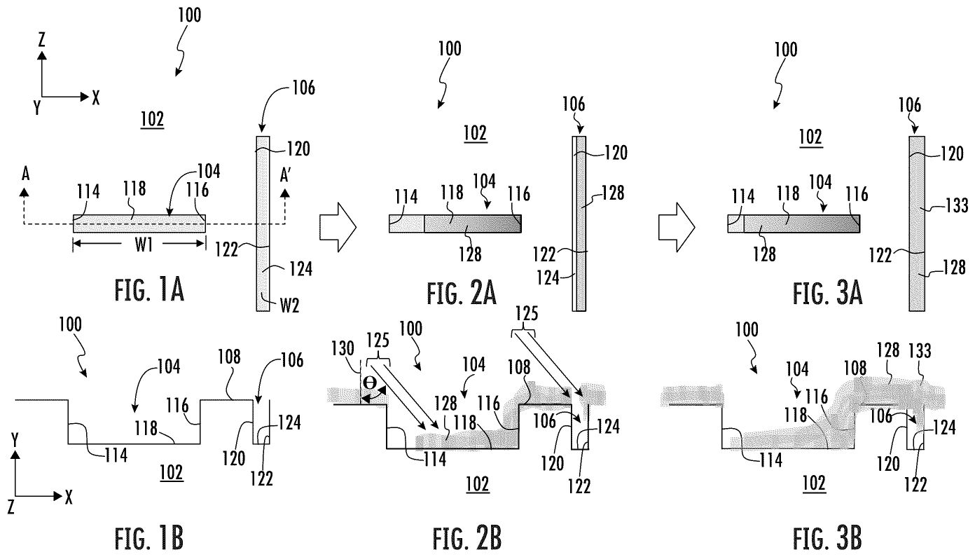

FIGS. 1A-1B depict a portion of a semiconductor device (hereinafter “device”) 100, such as a semiconductor layer 102, according to one or more embodiments. The semiconductor layer 102 may be a substrate or may be a layer(s) formed atop a substrate. As shown, the semiconductor layer 102 may include a plurality of trenches formed therein, such as a first trench 104 and a second trench 106. The first trench 104 and the second trench 106 may be recessed below a plane (e.g., x-z plane) defined by an upper surface 108 of the semiconductor layer 102. In the non-limiting embodiment shown, the first trench 104 may extend primarily along a first direction (e.g., x-direction), while the second trench 106 may extend primarily along a second direction (e.g., z-direction). The first and second trenches 104, 106 may be separated by a portion of the semiconductor layer 102, as shown. The first trench 104 may have a first width ‘W1’, in the x-direction, and the second trench 106 may have a second width ‘W2’, in the x-direction. In the embodiment shown, W1 is greater than W2. Embodiments herein are not limited in this context, however. Furthermore, in various embodiments, the depth of the first trench 104 and the second trench 106 may be different or the same.

The first trench 104 may be defined by a first sidewall 114 opposite a second sidewall 116, and bottom surface 118 extending between the first sidewall 114 and the second sidewall 116. Similarly, the second trench 106 may be defined by a first sidewall 120 opposite a second sidewall 122, and a bottom surface 124 extending between the first sidewall 120 and the second sidewall 122.

As shown in FIGS. 2A-2B, a film 128 may be formed over the semiconductor layer 102, including within the first trench 104 and the second trench 106. In some embodiments, the film 128 may be formed by delivering ions 125 to the semiconductor layer 102 at a non-zero angle ⊖ (FIG. 2B) relative to a perpendicular 130 extending from the upper surface 108 of the semiconductor layer 102. Although non-limiting, the ion species may include C, H, Si, N, O, Al, and Ti, including combinations thereof (e.g., CH4, CH3+, etc.). In the case the film 128 is a sacrificial layer (e.g., used only for patterning), C, H and/or O or other patterning hardmask type elements are more often considered.

As shown, the film 128 may be formed along the upper surface 108 of the semiconductor layer 102, along second sidewall 116 of the first trench 104, and along the bottom surface 118 of the first trench 104. Due to the non-zero angle θ, the ions 125 may not fully penetrate the second trench 106. Instead, the film 128 may be formed only partially along the second sidewall 122 of the second trench 106. In this embodiment, the film 128 may not be formed along the bottom surface 124 the second trench 106. The film 128 may also not be formed along the first sidewall 120 of the second trench 106 or along the first sidewall 114 of the first trench 104. It will be appreciated that the angled ions 125 may be delivered to the semiconductor layer 102 at different angles of incidence and direction to influence penetration of the ions 125 into the first trench 104 and the second trench 106, and thus control the location of the formation of the film 128. Furthermore, the ions 125 may be delivered in one or more processing steps.

As shown in FIGS. 3A-3B, the film 128 may be further formed over the semiconductor layer 102, including over the second trench 106, using another deposition process (not shown), which may be the same or different as the deposition process demonstrated in FIGS. 2A-2B. In this embodiment, the film 128 may pinch off the second trench 106, forming a bridge 133 and a cavity within the second trench 106, beneath the bridge 133. The film 128 may also be formed closer to the first sidewall 114 of the first trench 104, along the bottom surface 118 of the first trench 104. However, as shown, the film 128 may still be prevented from being formed directly along the first sidewall 114 of the first trench 104 by the angle of deposition.

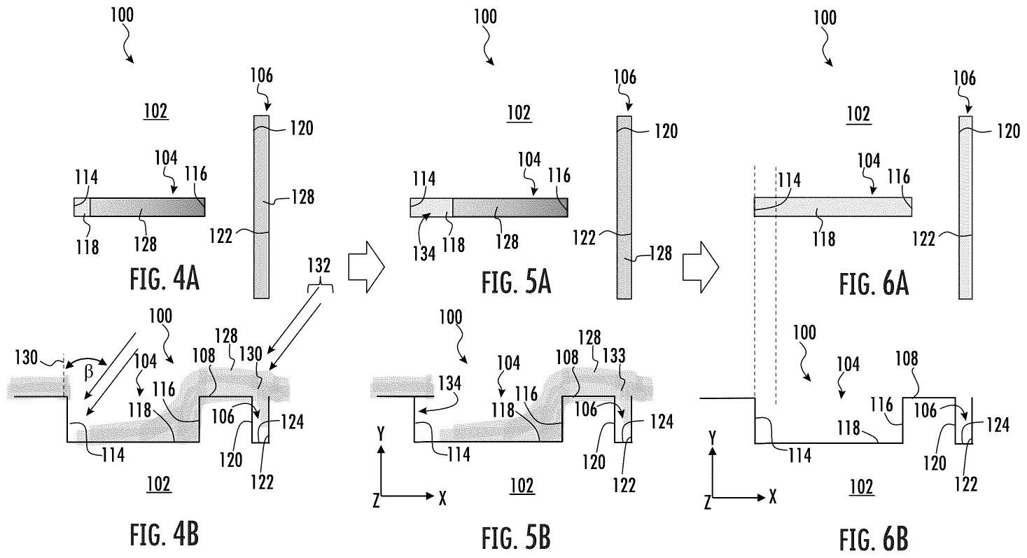

As shown in FIGS. 4A-4B, ions 132 may be delivered into the semiconductor layer 102 in a reactive ion etching (RIE) process to remove material from the first sidewall 114 of the first trench 104. The ions 132 may be delivered to the semiconductor layer 102 at a non-zero angle β (FIG. 4B) relative to the perpendicular 130 extending from the upper surface 108 of the semiconductor layer 102. Due to the presence of the film 128 over the second trench 106 and within the first trench 104, the ions 132 only impact the first sidewall 114, which remains exposed. Etching of the first sidewall 114 is further influenced by the non-zero angle β, which may be between 15-65°, and the aspect ratio of the first trench 104. The RIE process causes the first trench 104 to elongate in the x-direction, and to form a cavity or recessed area 134 beneath a portion of the film 128, as shown in FIGS. 5A-5B. It will be appreciated that the angled ions 132 may be delivered to the semiconductor layer 102 using multiple exposures at different angles of incidence and direction. Although non-limiting, the ions 132 of the etch process may include F, Cl, Br, C, H, O, Ar, N, S, and others, including combinations thereof (e.g., CH4, CH3+, etc.). In various embodiments, the species may be selected so that ions 132 are selective to the semiconductor layer 102 instead of the film 128.

As shown in FIGS. 6A-6B, the film 128 may then be removed (e.g., etched) from over the semiconductor layer 102, including from within the first and second trenches 104, 106. What remains is an elongated first trench 104 and a second trench 106 that is generally unchanged from the original.

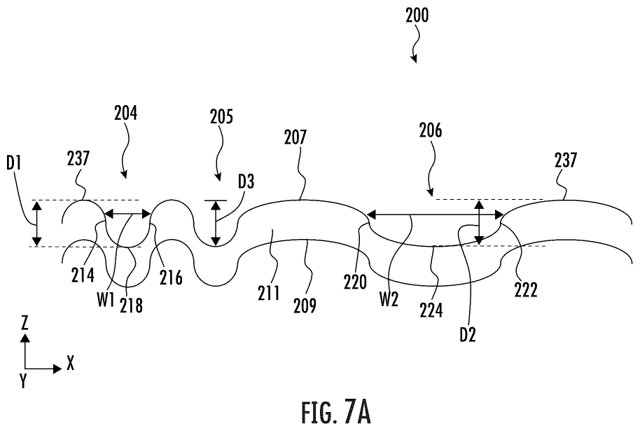

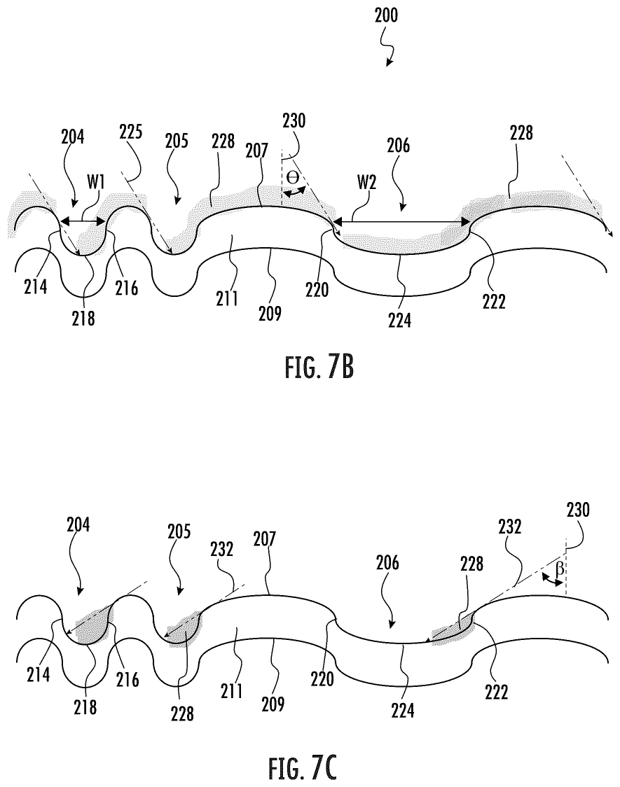

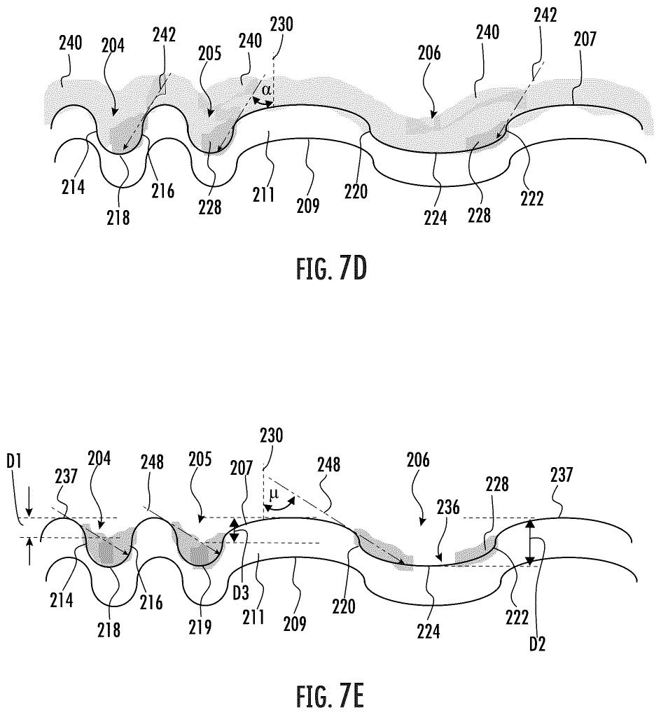

FIG. 7A demonstrates a top view of a portion of another semiconductor device (hereinafter “device”) 200 according to one or more embodiments. The device 200 may include a patterned layer (e.g., photoresist) having a plurality of device features, such as a plurality of lines 203, one of which is shown. In various embodiments, the plurality of lines 203 may form part of a larger pattern of features disposed on a silicon wafer or other substrate. The line 203 may include a first line sidewall 207, a second line sidewall 209, and an upper surface 211 connecting the first and second line sidewalls 207, 209.

During formation, one or more of the lines 203 may exhibit defects in the form of one or more indentations or trenches, such as trenches 204, 205, and 206 formed in the first line sidewall 207 thereof. In some cases, these defects are referred to as width roughness (LWR) and line edge roughness (LER). The first trench 204 may have a first width ‘W1’, in the horizontal x-direction, and the second trench 206 may have a second width ‘W2’, in the horizontal x-direction. In the embodiment shown, W2 is greater than W1. A width of the third trench 205 may be the same, or approximately the same, as W1. Embodiments herein are not limited in this context, however. As further shown, the first trench 204 may have a first depth, ‘D1’, the second trench 206 may have a second depth, ‘D2’, and the third trench 205 may have a third depth, ‘D3’. For each trench, the depth may be measured (e.g., in the z-direction) between a bottommost point of each respective bottom surface to an uppermost point of an adjacent crest or apex 237. Although shown here as being substantially the same, in other embodiments the depth of the first trench 204, the second trench 206, and/or the third trench 205 may be different.

The first trench 204 may be defined by a first sidewall 214 opposite a second sidewall 216, and bottom surface 218 extending between the first sidewall 214 and the second sidewall 216. Similarly, the second trench 206 may be defined by a first sidewall 220 opposite a second sidewall 222, and a bottom surface 224 extending between the first sidewall 220 and the second sidewall 222. Although the bottom surface 218 of the first trench 204 and the bottom surface 224 of the second trench 206 are shown as being curved, each may include one or more flat portions in some embodiments.

As shown in FIG. 7B, a film 228 may be formed over the semiconductor layer 202, including within the first trench 204, the second trench 206, and the third trench 205. In some embodiments, the film 228 may be a layer formed by delivering ions 225 to the semiconductor layer 202 at a non-zero angle ⊖ relative to a perpendicular 230 extending from the first line sidewall 207 of the semiconductor layer 202. As shown, the film 228 may be formed along the first line sidewall 207 of the semiconductor layer 202, along the second sidewalls 216, 222 of the first and second trenches 204, 206, and along the bottom surfaces 218, 224 of the first and second trenches 204, 206. Due to the non-zero angle ⊖, the ions 225 may not impact the first sidewalls 214, 220 of the first and second trenches 204, 206. As a result, the film 228 may not be formed along the first sidewalls 214, 220 of the first and second trenches 204, 206. It will be appreciated that the angled ions 225 may be delivered to the semiconductor layer 202 at different angles of incidence and direction to influence penetration of the ions 225 into the first trench 204 and the second trench 206, and thus control the location of the formation of the film 228.

As shown in FIG. 7C, ions 232 may be delivered into the semiconductor layer 202 in a RIE process to remove material from the device 200. More specifically, the ions 232 may be delivered to the semiconductor layer 202 at a non-zero angle β relative to the perpendicular 230 extending from the first line sidewall 207 of the semiconductor layer 202. Although nonlimiting, the non-zero angle β of ions 232 may be greater than the non-zero angle ⊖ of the ions 225. In this embodiment, only the film 228 is removed, primarily from the first line sidewall 207 of the semiconductor layer 202 and from the first sidewalls 214, 220 of the first and second trenches 204, 206. The film 228 may also be removed from a majority of the bottom surface 224 of the second trench 206. As shown, a portion of the film 228 remains within the trenches 204-206, along the second sidewalls 216 and 222, respectively.

As shown in FIG. 7D, device 200 may be rotated (or the deposition tool rotated relative to the semiconductor layer 202), and another layer of film 240 may be formed over the semiconductor layer 202. More specifically, the film 240 be formed over the semiconductor layer 202, including within the first trench 204, the second trench 206, and the third trench 205. In some embodiments, the film 240 may be formed by delivering ions 242 to the semiconductor layer 202 at a non-zero angle α relative to the perpendicular 230 extending from the first line sidewall 207 of the semiconductor layer 202. As shown, the film 240 may be formed along the first line sidewall 207 of the semiconductor layer 202, along the first sidewalls 214, 220 of the first and second trenches 204 and 206, along the bottom surfaces 218, 224 of the first and second trenches 204 and 206, and atop the film 228. It will be appreciated that the angled ions 242 may be delivered to the semiconductor layer 202 at different angles of incidence and direction to influence formation of the film 240. For example, the ions 242 may be delivered vertically in other embodiments.

As shown in FIG. 7E, ions 248 may be delivered into the semiconductor layer 202 in a second RIE process to remove material from the device 200. More specifically, the ions 248 may be delivered to the semiconductor layer 202 at a non-zero angle μ relative to the perpendicular 230 extending from the first line sidewall 207 of the semiconductor layer 202 to remove portions of the film 240. As shown, the film 240 is removed primarily from the crests or apices 237 of the first line sidewall 207 of the semiconductor layer 202 and from a middle portion 236 of the bottom surface 224 of the second trench 206. However, a portion of the film 240 remains along the first and second sidewalls 214, 216 of the first trench 205, and along the first and second sidewalls 216, 222 of the second trench 206. The film 240 and/or the film 228 further remains along the bottom surface 218 of the first trench 204, and along a bottom surface 219 of the third trench 205. Beneficially, the film 240 and/or the film 228 remains within each of the trenches 204, 205, 206 to reduce a depth of one or more of the trenches 204, 205, 206. That is, the first line sidewall 207 of the semiconductor layer 202 can be “smoothed” by reducing D1, D2, and/or D3 from those values originally demonstrated in FIG. 7A. As shown in FIG. 7E, D1 and D3 has been reduced, while D3 remains the same because no film is present along the middle portion 236 of the bottom surface 224 of the second trench 206.

Although not shown, the same processes shown and described can be repeated along the second line sidewall 209 to smooth/reduce any indentations or trenches present therein.

In some embodiments, a material of the film 228 and the semiconductor layer 202 may be the same or similar. As such, the film 228 can remain in the device 200 as part of the new/modified line, but with enhanced properties (e.g., smoother). Furthermore, etch/pattern transfer steps can be done resulting in the deposition of the film 228 being a sacrificial layer that serves primarily to improve the end result of that pattern transfer.

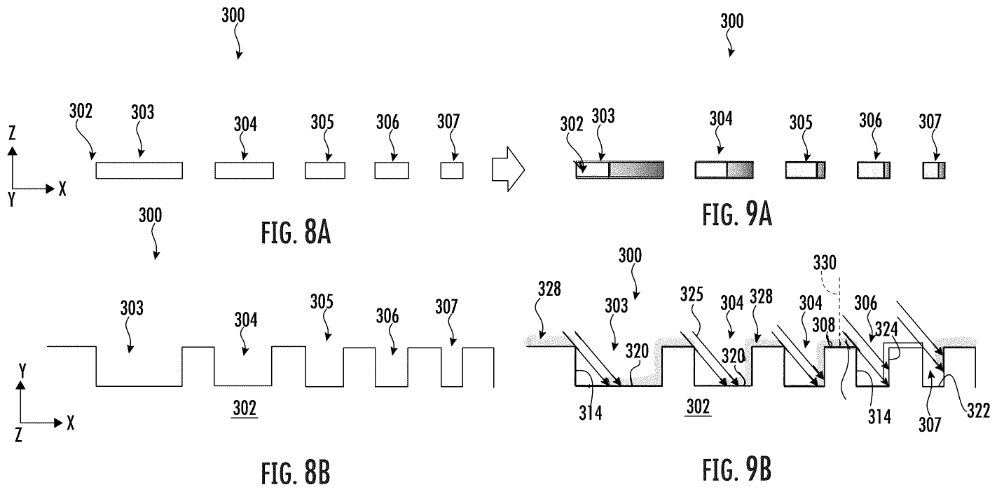

FIG. 8A demonstrates a top view and FIG. 8B demonstrates a side view of a portion of another semiconductor device (hereinafter “device”) 300 according to one or more embodiments. The device 300 may the same or similar to the device 100 described above. As such, only certain aspects of the device 300 will hereinafter be described for the sake of brevity. The device 300 may include a plurality of trenches 303-307 formed in a semiconductor layer 302, wherein a width (e.g., in the x-direction) of each of the trenches 303-307 varies. In other embodiments, two or more of the trenches 303-307 may have the same or similar widths.

As shown in FIGS. 9A-9B, a film 328 may be formed over the semiconductor layer 302, including within each of the trenches 303-307. In some embodiments, the film 328 may be formed by delivering ions 325 to the semiconductor layer 302 at a non-zero angle ⊖ (FIG. 9B) relative to a perpendicular 330 extending from an upper surface 308 of the semiconductor layer 302. As shown, due to the non-zero angle ⊖, the ions 325 generally do not impact the first sidewalls 314 of each of the trenches 303-307. However, the ions 325 impact portions of a bottom surface 320 of trenches 303, 304, and 305 without impacting any of a bottom surface 322 of trenches 306 and 307. Furthermore, as the width of the trenches becomes narrower (e.g., in the x-direction), the film 328 is formed only along a portion of a second sidewall 324 of trenches 306 and 307, for example, as shown.

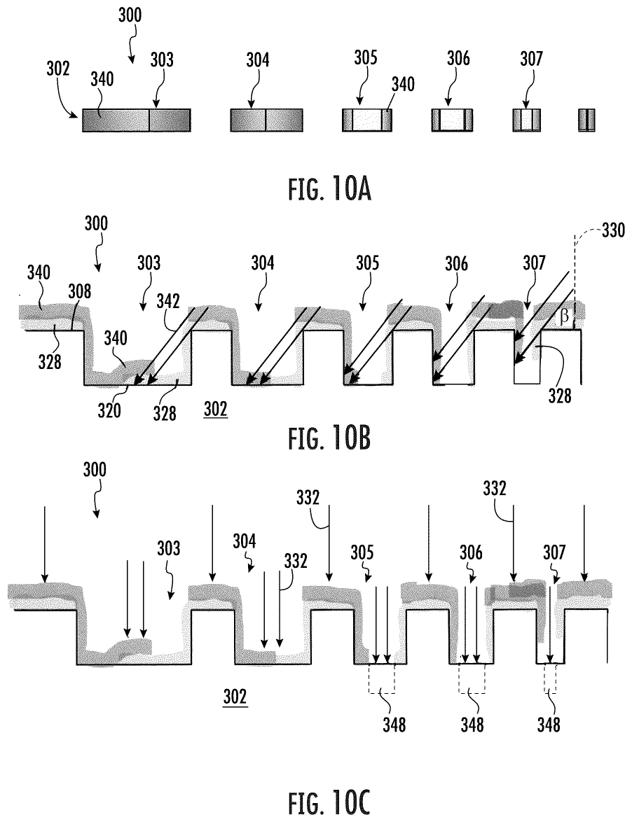

The device 300 and/or the processing tool(s) may be rotated, and another layer of film 340 may be formed over the semiconductor layer 302, as shown in FIGS. 10A-10B. The film 340 may be formed within each of the trenches 303-307, as well as over the upper surface 308 of the semiconductor layer 302. In some embodiments, the film 340 may be formed by delivering ions 342 to the semiconductor layer 302 at a non-zero angle β relative to the perpendicular 330 extending from the upper surface 308 of the semiconductor layer 302. As demonstrated, film 340 may be formed directly atop film 328 in certain areas of the device 300. More specifically, the films 328, 340 may overlap one another along a portion of the bottom surface 320 of trench 303. However, within trenches 305, 306, and 307, for example, the films 328, 340 are spaced apart from one another along the bottom surface. It will be appreciated that the location of the formation of the films 328, 340 is dependent upon the aspect ratios of each trench 303-307, as well as the incident angles the ions are delivered to the semiconductor layer 302 during deposition.

As shown in FIG. 10C, ions 332 may be delivered into the semiconductor layer 302 in a vertical etch process to remove material from the device 300. More specifically, the ions 332 may be delivered to the semiconductor layer 302 vertically to impact those areas of the trenches 303-307 remaining exposed following formation of films 328, 340. Due to the etch resistance of the films 328 and 340, the ions 332 do not substantially impact the surfaces of trenches 303 and 304. However, the opening between the films 328 and 340 in each of trenches 305, 306, and 307 permits the ions 332 to remove material from semiconductor layer 302, forming secondary trenches or recesses 348 therein. Although not shown, the films 328, 340 may then be removed from one or more surfaces of the semiconductor layer 302.

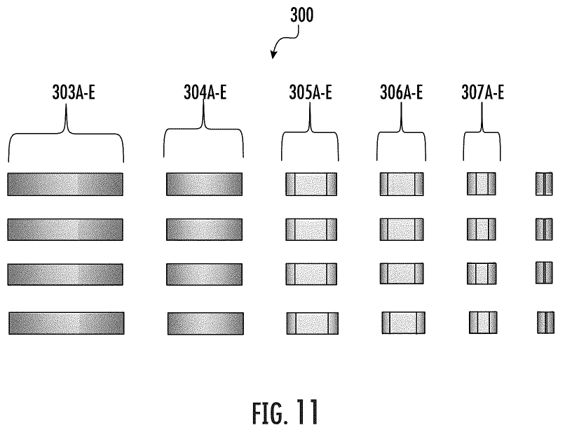

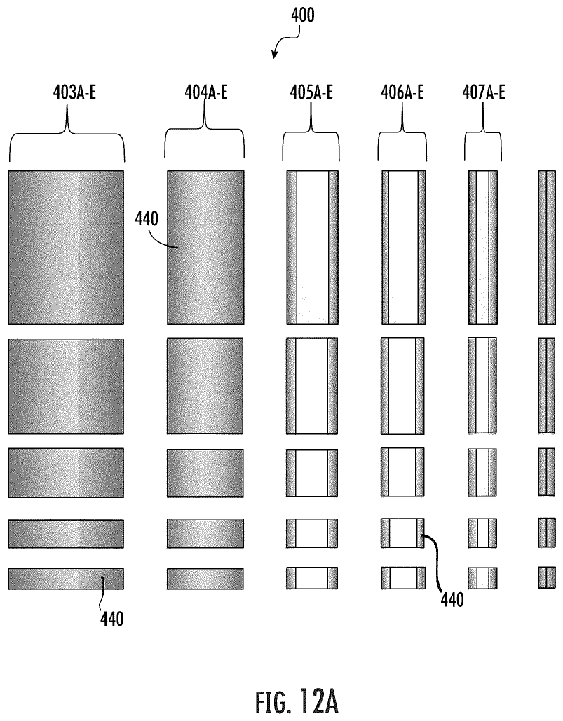

FIG. 11 shows an application of the film deposition and etch processes of FIGS. 10A-10C when the device 300 includes an array of trenches. For example, each of trenches 303A-303D is processed the same or similar as trench 303 in FIGS. 10A-10C, each of trenches 304A-304D is processed the same or similar as trench 304 in FIGS. 10A-10C, and so. In this embodiment, each of trenches 305A-305D, 306A-306D, and 307A-307D is etched, while each of trenches 303A-303D and 304A-304D is not etched.

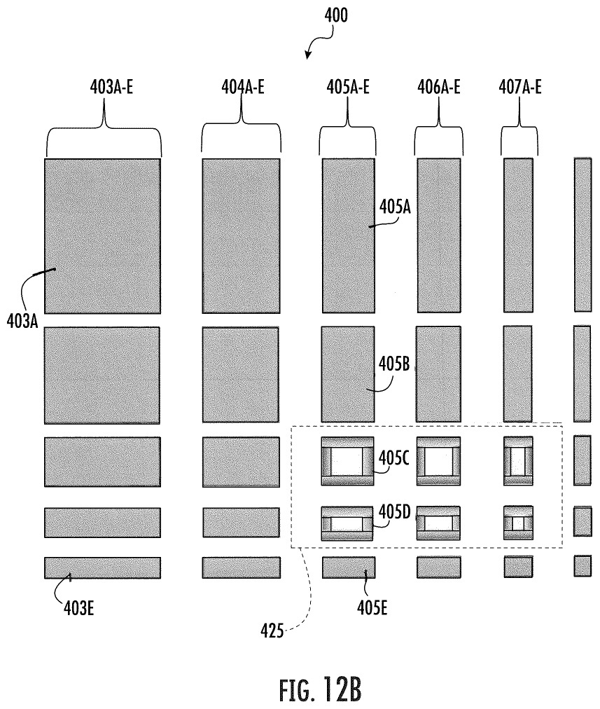

In another example, shown in FIGS. 12A-12B, multiple deposition steps with wafer twist can be used to further down-select features to etch of device 400. FIG. 12A represents an array of trenches 403-407 following deposition of one or more film layers 440, while FIG. 12B represents the array of trenches 403-407 following one or more etch steps. As shown, not all trenches in each column are etched the same, and only those trenches in a desired etch area 425 may be etched (e.g., trenches 405C, 405D, 406C, 406D, 407C, and 407D). It will be appreciated that other etch areas 425 may be selected based, in part, on incident angles the ions are delivered to the semiconductor layer 302 during deposition and/or etching.

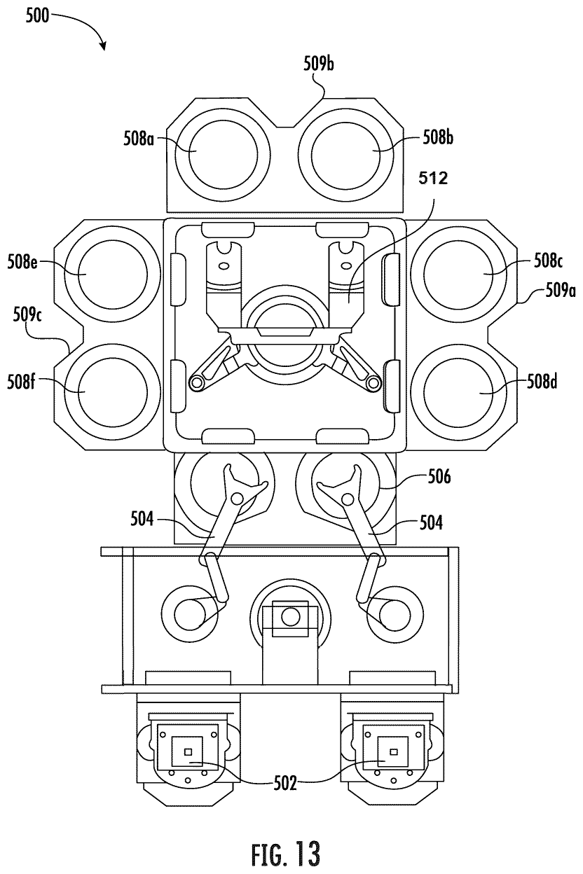

FIG. 13 illustrates a top plan view of one embodiment of another processing system 500 including a plurality of chambers according to some embodiments. As shown, a pair of front opening unified pods 502 supply substrates of a variety of sizes that are received by robotic arms 504 and placed into a holding area 506 before being placed into one of the substrate processing chambers 508a-f, positioned in tandem sections 509a-c. A second robotic arm 510 may be used to transport the substrate wafers from the holding area 506 to the substrate processing chambers 508a-f and back. Each substrate processing chamber, 508a-f, can be outfitted to perform a number of substrate processing operations described herein such as film layer deposition, ion etching, and other substrate processes.

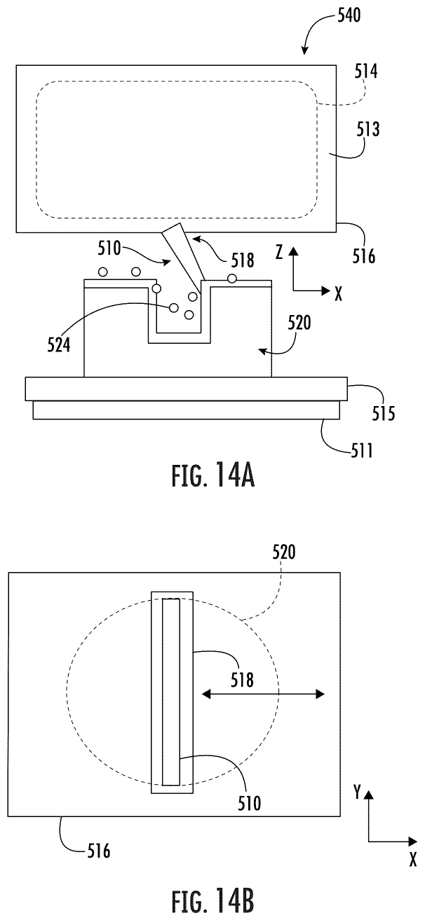

The substrate processing chambers 508a-f may include one or more system components for depositing, treating, growing, annealing, curing, implanting, and/or etching the substrate and/or a substrate layer on the substrate or wafer. In one configuration, two pairs of the processing chambers, for example 508a-b, may be used to deposit one or more film layers over the substrate. Another two pairs of the processing chambers, for example 508c-d, may be used to etch the substrate and/or the film layers formed thereon. For example, processing chambers 508c-d may include a compact plasma processing system 540, as shown in FIGS. 14A-14B.

The system 540 may be operable to generate an ion beam shown as ions 510. The system 540 may be appropriate for performing one or more of the removal processes shown in FIG. 4B, FIG. 6B, and FIG. 10C, wherein ions 510 may be the same or similar to the etching ions described in connection with these figures. More specifically, a substrate 520 may be exposed to reactive neutral species 524, where the reactive neutral species 524 are derived from precursor gas composition used to generate the RIE plasma. The reactive neutral species 524 may arrive to the substrate 520, where every portion of the different exposed surfaces of the substrate 520 are impacted by the reactive neutral species 524. Notably, the present embodiments harness the principles of RIE processing where etching of a given surface is enhanced in the presence of ions. Notably, in accordance with the present embodiments, etching may take place just in regions of the substrate 520 impacted by the directional ions, i.e., in regions impacted by the ions 510, while leaving other surfaces unetched.

The ion beam may be extracted from a plasma 514 generated in a plasma chamber 513 by any known technique. The processing apparatus 540 may include an extraction plate 516 having an extraction aperture 518, where the ions are extracted as an ion beam from the plasma 514 and directed to the substrate 520. As shown in FIG. 14B, the extraction aperture 518 may be elongated along the Y-axis, providing a ribbon ion beam extending, for example, over an entire substrate along the direction parallel to the Y-axis. In various embodiments, the substrate 520 may be disposed on a substrate holder 515 and scanned along the X-axis to provide coverage at different regions of the substrate 520 or over the entirety of the substrate 520. In other embodiments, the extraction aperture 518 may have a different shape such as a square or circular shape.

In some embodiments, the plasma chamber 513 may also serve as a deposition process chamber to provide material for depositing on the substrate 520 in the deposition operation preceding etching, such as the deposition of the film layer(s). The substrate holder 515 may further include a heater assembly 511 for selectively heating the substrate 520 to different temperatures in different regions within the X-Y plane for selectively changing the amount of depositing material as discussed above.

During an ion exposure, reactive species may be provided or created in the plasma chamber 513 and may also impinge upon the substrate 520. While various non-ionized reactive species may impinge upon all surfaces of substrate 520, including different surfaces in one or more of the trenches, etching may take place in areas impacted by the ions 510, as in known RIE processes, while little or no etching takes place in regions not impacted by ions 510.

In further embodiments, directional etching of ions may be performed by rotating a substrate within the X-Y plane to any desired angle. Thus, a trench feature may be oriented with its long axis at a 45-degree angle with respect to the Y-axis while a ribbon beam directed to the trench feature has its axis oriented along the Y-axis as in FIG. 14B.

In additional embodiments, by scanning the substrate 520 with respect to the ion beam 510, such as along the X-axis as generally shown in FIG. 14B, the possibility is afforded to vary a directed etch across the substrate 520 to achieve location-specific directional selectivity of etching, so features within a certain region may be altered to one extent while features in another region are not altered or are altered to a different extent or in a different fashion.

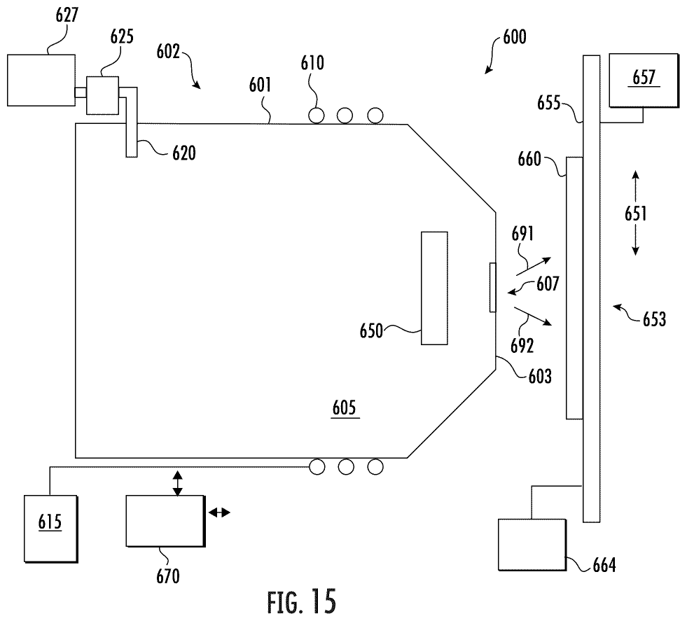

Another two pairs of the processing chambers of processing system 500, for example 508e-f, may include a semiconductor processing apparatus used to create the directional etching, such as the apparatus 600 shown in FIG. 15. The apparatus 600 may be useful to perform one or more of the smoothing or etching processes shown in FIG. 7C and/or FIG. 7E. The apparatus 600 includes an ion source 602, including an ion source chamber 605, comprised of a plurality of chamber walls 601. In certain embodiments, one or more of these chamber walls 601 may be constructed of a dielectric material, such as quartz. An RF antenna 610 may be disposed on an exterior surface of one or more of these chamber walls. In certain embodiments, the RF antenna 610 may wrap around the exterior of the ion source 602. The RF antenna 610 may be powered by a RF power supply 615. The energy delivered to the RF antenna 610 is radiated within the ion source chamber 605 to ionize a feed gas, which is introduced via gas inlet 620. The gas inlet 620 may be in communication with an ion source mass flow controller 625, or similar mechanism to control the flow of gas from the gas container 627 to the ion source chamber 605.

Further, while only one gas container 627 and ion source mass flow controller 625 are shown, it is understood that there may be a plurality of gas containers that contain various gasses that may be introduced into the ion source chamber 605. Each gas container 627 may have a respective mass flow controller. In this way, the controller 670 may select both the species that is introduced into the ion source chamber 605, as well as its flow rate.

One chamber wall, referred to as the extraction plate 603 includes an extraction aperture 607 through which ions may exit the ion source chamber 605. The extraction plate 603 may be constructed of an electrically conductive material, such as titanium, tantalum or another metal, of an electrically insulating material such as alumina, Al₂O₃ or another insulator, or a combination of conductive and insulating materials. The extraction plate 603 may be in excess of 300 millimeters in width, but embodiments herein are not limited as such. Further, the extraction aperture 607 may be wider than the diameter of the workpiece 660. The longer dimension, or width, may be referred to as the X direction, while the short dimension, or height, may be referred to as the Y direction with the workpiece 660 scanning motion being parallel to the Y direction. This extraction plate 603 may be biased at an extraction voltage. In other embodiments, the extraction plate 603 may be grounded.

Disposed within the ion source chamber 605 may be a blocker 650, which may be a dielectric material that is used to affect the plasma sheath in the vicinity of the extraction aperture 607. For example, in certain embodiments, the blocker 650 is disposed such that the ions exit the extraction aperture 607 at an extraction angle that is not perpendicular to the workpiece 660. In certain embodiments, ions may be extracted at two different extraction angles. In this embodiment, a first beamlet 691 and a second beamlet 692 are directed toward the workpiece 660. In other embodiments, the ions are extracted at a single extraction angle. The placement of the blocker 650 within the ion source chamber 605 relative to the extraction aperture 607 defines the angle or angles at which the ions impact the workpiece 660.

A movable workpiece holder 653 is disposed proximate the extraction aperture 607. The movable workpiece holder 653 includes a platen 655 on which the workpiece 660 is disposed. The platen 655 is scanned using a scan motor 657, which moves the platen 655 in the direction 651. As stated above, the direction 651 is parallel to the Y-direction. In certain embodiments, the movable workpiece holder 653 may be rotated about the center of the workpiece 660, so as to create a non-zero twist angle. In certain embodiments, the platen 655 may be biased using a workpiece bias power supply 664, wherein the output from the workpiece bias power supply 664 is a pulsed DC voltage, having a frequency of between 5 kHz and 50 kHz and an amplitude of zero to 5,000 volts.

Additionally, the apparatus 600 may include a controller 670, including a processing unit, such as a microcontroller, a personal computer, a special purpose controller, or another suitable processing unit. The controller 670 may also include a non-transitory computer readable storage element, such as a semiconductor memory, a magnetic memory, or another suitable memory. This non-transitory storage element may contain instructions and other data that allows the controller 670 to perform the functions described herein. The controller 670 may be capable of controlling the species and the flow rate of gasses into the ion source chamber 605 by providing controls to one or more of the ion source mass flow controllers 625. Additionally, the controller 670 may be capable of controlling the energy supplied to the ion source chamber 605 via control of RF power supply 615. The controller 670 may also control the motion and bias of the workpiece 660 through control of scan motor 657 and workpiece bias power supply 664.

The apparatus 600 may be used to perform directional etching processes. Specifically, as described above, in certain embodiments, the blocker 650 may be used to alter the angle at which ions exit through the extraction aperture 607. Specifically, the blocker 650 affects the angle relative to the Y-direction, but does not affect the angle relative to the X direction. In other embodiments, the placement of the blocker 650 may be fixed, such that the first beamlet 691 and the second beamlet 692 impact the workpiece 660 at an angle between approximately 15° and approximately 45°.

Referring again to FIG. 13, it will be appreciated that any one or more of the processes described may be carried out in additional chambers separated from the fabrication system shown in different embodiments. It will be appreciated that additional configurations of deposition, treating, growing, etching, annealing, and curing chambers for substrates and material layers are contemplated by the processing system 500. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 500, or more specifically, chambers incorporated into the processing system 500 or other processing systems, may be used to produce structures according to some embodiments of the present disclosure.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a semiconductor layer including a plurality of trenches, wherein a first trench of the plurality of trenches has a first trench width extending in a first direction, wherein a second trench of the plurality of trenches has a second trench width extending in the first direction, wherein the first trench width and the second trench width are different, and wherein the first and second trenches each include a first sidewall opposite a second sidewall, and a bottom surface extending between the first and second sidewalls;
depositing a film atop the semiconductor layer, wherein the film is delivered at a non-zero angle relative to a perpendicular extending from a top surface of the semiconductor layer, and wherein an amount of the film formed along the bottom surface of the first trench is greater than an amount of the film formed along the bottom surface of the second trench; and
delivering ions into the semiconductor layer in a reactive ion etching process to remove material from at least one of: the first sidewall of the first trench, the bottom surface of the second trench, and the film.

2. The method of claim 1, wherein depositing the film atop the semiconductor layer comprises forming the film along an entire height of the second sidewall of the first trench, and forming the film only along a portion of the second sidewall of the second trench.

3. The method of claim 2, wherein forming the film only along the portion of the second sidewall of the second trench comprises forming the film over the second trench to enclose a cavity within the second trench.

4. The method of claim 1, wherein the ions of the reactive ion etching process are delivered at a second non-zero angle relative to the perpendicular extending from the top surface of the semiconductor layer, wherein the second non-zero angle is different than the non-zero angle, and wherein the ions remove material from the first sidewall of the first trench without removing material from the first sidewall of the second trench.

5. The method of claim 1, wherein the ions of the reactive ion etching process are delivered parallel to the perpendicular extending from the top surface of the semiconductor layer, and wherein the ions remove material from the bottom surface of the second trench without removing material from the bottom surface of the first trench.

6. The method of claim 1, wherein depositing the film atop the semiconductor layer comprises:
depositing the film over the top surface of the semiconductor layer and along the second sidewall of the first and second trenches in a first deposition process; and
depositing the film over the top surface of the semiconductor layer and along the first sidewall of the first and second trenches in a second deposition process, wherein the second deposition process is performed after a first etch process to remove the film from the top surface of the semiconductor layer.

7. The method of claim 6, further comprising performing a second etch process to remove the film from the top surface of the semiconductor layer.

8. The method of claim 1, wherein the semiconductor layer comprises a line feature, and wherein the film is deposited along a first side of the line feature.

9. The method of claim 1, wherein a first aspect ratio of the first trench is different than a second aspect ratio of the second trench, and wherein the first trench width is greater than the second trench width.

10. A method, comprising:
providing a substrate including a plurality of trenches, wherein a first trench of the plurality of trenches has a first trench width extending in a first direction, wherein a second trench of the plurality of trenches has a second trench width extending in the first direction, wherein the first trench width is greater than the second trench width, and wherein the first and second trenches each include a first sidewall opposite a second sidewall, and a bottom surface extending between the first and second sidewalls;
depositing a film atop the substrate, wherein the film is delivered at a non-zero angle relative to a perpendicular extending from a top surface of the substrate, and wherein an amount of the film formed along the bottom surface of the first trench is greater than an amount of the film formed along the bottom surface of the second trench; and
delivering ions into the substrate in a reactive ion etching process to remove material from at least one of: the first sidewall of the first trench, the bottom surface of the second trench, and the film.

11. The method of claim 10, wherein depositing the film atop the substrate comprises forming the film along an entire height of the second sidewall of the first trench, and forming the film only along a portion of the second sidewall of the second trench.

12. The method of claim 11, wherein forming the film only along the portion of the second sidewall of the second trench comprises forming the film over the second trench to enclose a cavity within the second trench.

13. The method of claim 10, wherein the ions of the reactive ion etching process are delivered at a second non-zero angle relative to the perpendicular extending from the top surface of the substrate, wherein the second non-zero angle is different than the non-zero angle, and wherein the ions remove material from the first sidewall of the first trench without removing material from the first sidewall of the second trench.

14. The method of claim 10, wherein the ions of the reactive ion etching process are delivered parallel to the perpendicular extending from the top surface of the substrate, and wherein the ions remove material from the bottom surface of the second trench without removing material from the bottom surface of the first trench.

15. The method of claim 10, wherein depositing the film atop the substrate comprises:
depositing the film over the top surface of the substrate and along the second sidewall of the first and second trenches in a first deposition process; and
depositing the film over the top surface of the substrate and along the first sidewall of the first and second trenches in a second deposition process, wherein the second deposition process is performed after a first etch process, wherein the first etch process removes the film from the top surface of the substrate, and wherein a second etch process is performed after the second deposition process to remove the film from the top surface of the substrate.

16. A system comprising:
a substrate including a plurality of trenches, wherein a first trench of the plurality of trenches has a first trench width extending in a first direction, wherein a second trench of the plurality of trenches has a second trench width extending in the first direction, wherein the first trench width and the second trench width are different, and wherein the first and second trenches each include a first sidewall opposite a second sidewall, and a bottom surface extending between the first and second sidewalls; and
a deposition device operable to deposit a film atop the substrate, wherein the film is delivered at a non-zero angle relative to a perpendicular extending from a top surface of the substrate, and wherein an amount of the film formed along the bottom surface of the first trench is greater than an amount of the film formed along the bottom surface of the second trench; and
an etch device operable to deliver ions into the substrate in a reactive ion etching process to remove material from at least one of: the first sidewall of the first trench, the bottom surface of the second trench, and the film.

17. The system of claim 16, wherein the deposition device is operable to form the film along an entire height of the second sidewall of the first trench, and to form the film only along a portion of the second sidewall of the second trench.

18. The system of claim 16, wherein the deposition device is further operable to form the film over the second trench to enclose a cavity within the second trench.

19. The system of claim 18, wherein the etch device delivers the ions of the reactive ion etching process at a second non-zero angle relative to the perpendicular extending from the top surface of the substrate, wherein the second non-zero angle is different than the non-zero angle, and wherein the ions remove material from the first sidewall of the first trench without removing material from the first sidewall of the second trench.

20. The system of claim 16, wherein the etch device delivers the ions of the reactive ion etching process parallel to the perpendicular extending from the top surface of the substrate, wherein the ions remove material from the bottom surface of the second trench without remove material from the bottom surface of the first trench.
